(19) United States
(12) Patent Application Publication
(10) Pub. No.: US 2023/0326841 A1
(43) Pub. Date: Oct. 12, 2023

(54) DUAL-SIDED PACKAGED RADIO-FREQUENCY MODULE HAVING BALL GRID ARRAY EMBEDDED IN UNDERSIDE MOLDING

(71) Applicant: SKYWORKS SOLUTIONS, INC., Irvine, CA (US)

(72) Inventors: Robert Francis Darveaux, Corona Del Mar, CA (US); Howard E. Chen, Anaheim, CA (US); Hoang Mong Nguyen, Fountain Valley, CA (US); Anthony James LoBianco, Irvine, CA (US)

(21) Appl. No.: 18/130,511

(22) Filed: Apr. 4, 2023

Related U.S. Application Data
(60) Provisional application No. 63/362,693, filed on Apr. 8, 2022.

(51) Int. Cl. H01L 23/498; H01L 23/538; H01L 23/31; H01Q 1/22

(52) U.S. Cl. CPC H01L 23/49816; H01L 23/5383; H01L 23/3157; H01L 23/3128; H01Q 1/2283

(57) ABSTRACT

A dual-sided packaged radio-frequency (RF) module comprises a packaging substrate having a first surface with at least one RF circuit component mounted thereon and a second surface opposite to the first surface with at least one circuitry component mounted thereon, at least one contact feature attached to the second surface of the packaging substrate, a vertical extension of the at least one contact feature being larger than a distance between a bottom surface of the at least one circuitry component and the second surface of the packaging substrate, an underside molding encapsulating the at least one circuitry component and the at least one contact feature, a bottom surface of the underside molding being flush with the bottom surface of the at least one circuitry component, and a trench structure formed in the underside molding around the at least one contact feature.

### CROSS-REFERENCE TO RELATED APPLICATIONS

This application claims priority under 35 U.S.C. § 119(e) to U.S. Provisional Patent Application Ser. No. 63/362,693, titled “DUAL-SIDED PACKAGED RADIO-FREQUENCY MODULE HAVING BALL GRID ARRAY EMBEDDED IN UNDERSIDE MOLDING,” filed Apr. 8, 2022, the entire content of which is incorporated herein by reference in its entirety for all purposes.

### BACKGROUND

### Technical Field

The present disclosure relates to packaged radio-frequency (RF) modules.

### Description of the Related Technology

In many radio-frequency (RF) implementations, one or more integrated circuits are disposed in a packaged module. Such a packaged module typically includes a packaging substrate and one or more semiconductor die mounted on the packaging substrate. The packaged module can also include one or more surface-mount technology (SMT) devices having, for example, respective passive circuit elements. Such SMT device(s) can also be mounted on the packaging substrate.

### SUMMARY

In accordance with some implementations, the present disclosure relates to a dual-sided packaged radio-frequency (RF) module that includes a packaging substrate. The packaging substrate has a first surface with at least one RF circuit component mounted thereon. The packaging substrate further has a second surface opposite to the first surface with at least one circuitry component mounted thereon. At least one contact feature is attached to the second surface of the packaging substrate. The vertical extension of the at least one contact feature is larger than the distance between the bottom surface of the at least one circuitry component and the second surface of the packaging substrate. The dual-sided packaged RF module further includes an underside molding encapsulating the at least one circuitry component and the at least one contact feature. The bottom surface of the underside molding is flush with the bottom surface of the at least one circuitry component. The dual-sided packaged RF module further includes a trench structure formed in the underside molding around the at least one contact feature.

In some embodiments, the at least one contact feature includes a solder ball. According to a number of embodiments, the solder ball has a diameter that is larger than the thickness of the underside molding. In certain embodiments, the diameter of the solder ball is larger than twice the thickness of the underside molding.

In several embodiments, the trench structure is formed circumferentially around the solder ball. In various embodiments, the trench structure comprises a recess of triangular or trapezoidal cross-section running around the edge of the portion of the solder ball exposed from the underside molding.

In a number of embodiments, the width of the recess of the trench structure gradually decreases when followed from the surface of the underside molding towards the second surface of the packaging substrate.

In some embodiments, the dual-sided packaged RF module comprises a number of contact features forming a ball grid array (BGA) or land grid array (LGA) on the bottom surface of the underside molding.

In various embodiments the dual-sided packaged RF module further comprises an overmold encapsulating the at least one RF circuit component mounted on the first surface of the packaging substrate.

According to a number of embodiments, the solder ball comprises a solder ball core enclosed by surrounding solder material. In some embodiments, the solder ball core is formed from a material different from the surrounding solder material. In several embodiments, the surrounding solder material includes a solder alloy. In some embodiments, the solder alloy includes at least one of tin (Sn), copper (Cu), bismuth (Bi), indium (In), antimony (Sb), or silver (Ag).

In some embodiments, the material of the solder ball core includes at least one of copper (Cu), nickel (Ni), silver (Ag), gold (Au), aluminum (Al), molybdenum (Mo), magnesium (Mg), zinc (Zn), cobalt (Co), or an alloy of any combination thereof.

In a number of embodiments, the solder ball core has the shape of a partially cut-away sphere, the cutting plane being flush with the surface of the underside molding.

According to various embodiments, the dual-sided packaged RF module is implemented as a power amplifier (PA) module, a low-noise amplifier (LNA) module, a front-end module (FEM), or a switching module.

The present disclosure further relates in several aspects to a dual-sided packaged radio-frequency (RF) module. The dual-sided packaged RF module comprises a packaging substrate. The packaging substrate has a first surface with at least one RF circuit component mounted thereon. The packaging substrate has a second surface opposite to the first surface with at least one circuitry component mounted thereon. At least one solder ball is attached to the second surface of the packaging substrate. The vertical extension of the at least one solder ball is larger than the distance between the bottom surface of the at least one circuitry component and the second surface of the packaging substrate. The at least one solder ball includes a solder ball core enclosed by surrounding solder material. The solder ball core is formed from a material different from the surrounding solder material. The dual-sided packaged RF module further comprises an underside molding encapsulating the at least one circuitry component and the at least one solder ball. The bottom surface of the underside molding is flush with the bottom surface of the at least one circuitry component.

In a number of embodiments, the dual-sided packaged RF module comprises a number of solder balls forming a ball grid array (BGA) on the bottom surface of the underside molding. In a number of embodiments, the vertical extension of the at least one solder ball is larger than twice the distance between the bottom surface of the at least one circuitry component and the second surface of the packaging substrate.

In some embodiments, the surrounding solder material includes a solder alloy. According to various embodiments, the solder alloy includes at least one of tin (Sn), copper (Cu), bismuth (Bi), indium (In), antimony (Sb), or silver (Ag).

In several embodiments, the material of the solder ball core includes at least one of copper (Cu), nickel (Ni), silver (Ag), gold (Au), aluminum (Al), molybdenum (Mo), magnesium (Mg), zinc (Zn), cobalt (Co), or an alloy of any combination thereof.

According to certain embodiments, the solder ball core has the shape of a partially cut-away sphere, the cutting plane being flush with the surface of the underside molding. In a number of embodiments, the distance between the cutting plane of the partially cut-away sphere and the surface of the underside molding is less than half the diameter of the sphere of the solder ball core.

In some embodiments, the dual-sided packaged RF module is implemented as a power amplifier (PA) module, a low-noise amplifier (LNA) module, a front-end module (FEM), or a switching module.

The present disclosure further relates in several aspects to a wireless device. The wireless device comprises a dual-sided packaged radio-frequency (RF) module, the dual-sided packaged RF module comprising a packaging substrate having a first surface with at least one RF circuit component mounted thereon and a second surface opposite to the first surface with at least one circuitry component mounted thereon, at least one contact feature attached to the second surface of the packaging substrate, the vertical extension of the at least one contact feature being larger than the distance between the bottom surface of the at least one circuitry component and the second surface of the packaging substrate, an underside molding encapsulating the at least one circuitry component and the at least one contact feature, the bottom surface of the underside molding being flush with the bottom surface of the at least one circuitry component, and a trench structure formed in the underside molding around the at least one contact feature. The wireless device further comprises an antenna coupled to the dual-sided packaged RF module.

In some embodiments, the dual-sided packaged RF module is implemented as a diversity receive (RX) module. According to several embodiments, the at least one RF circuit component includes one or more surface-mount technology (SMT) devices. In various embodiments, the at least one circuitry component mounted on the second surface of the packaging substrate includes at least one of power amplifiers (PA), low noise amplifiers (LNA), or switches. According to a number of embodiments, the at least one contact feature is a solder ball. In a number of embodiments, the vertical extension of the at least one solder ball is larger than twice the distance between the bottom surface of the at least one circuitry component and the second surface of the packaging substrate.

The present disclosure further relates in several aspects to a wireless device. The wireless device comprises a dual-sided packaged radio-frequency (RF) module, the dual-sided packaged RF module comprising a packaging substrate having a first surface with at least one RF circuit component mounted thereon and a second surface opposite to the first surface with at least one circuitry component mounted thereon, at least one solder ball attached to the second surface of the packaging substrate, the vertical extension of the at least one solder ball being larger than the distance between the bottom surface of the at least one circuitry component and the second surface of the packaging substrate, the at least one solder ball including a solder ball core enclosed by surrounding solder material, the solder ball core being formed from a material different from the surrounding solder material, and an underside molding encapsulating the at least one circuitry component and the at least one solder ball, the bottom surface of the underside molding being flush with the bottom surface of the at least one circuitry component. The wireless device further comprises an antenna coupled to the dual-sided packaged RF module.

In some embodiments, the dual-sided packaged RF module is implemented as a diversity receive (RX) module. According to several embodiments, the at least one RF circuit component includes one or more surface-mount technology (SMT) devices. In various embodiments, the at least one circuitry component mounted on the second surface of the packaging substrate includes at least one of power amplifiers (PA), low noise amplifiers (LNA), or switches.

The present disclosure further relates in several aspects to a method of forming a dual-sided packaged radio-frequency (RF) module. The method comprises mounting at least one RF circuit component on a first surface of a packaging substrate and at least one circuitry component on a second surface of the packaging substrate opposite to the first surface. The method further comprises attaching at least one contact feature to the second surface of the packaging substrate so that the vertical extension of the at least one contact feature is larger than the distance between the bottom surface of the at least one circuitry component and the second surface of the packaging substrate. The method further comprises encapsulating the at least one contact feature and the at least one circuitry component with encapsulating molding material. The method further comprises thinning down the encapsulating molding material so that the material of the at least one contact feature is exposed from the bottom surface of the encapsulating molding material. The method further comprises forming a trench structure in the thinned down underside molding around the at least one contact feature.

In some embodiments, the method further comprises re-forming the at least one contact feature by forming a cap of solder material on the portion of the at least one contact feature which is exposed from the bottom surface of the encapsulating molding material.

According to a number of embodiments, the at least one contact feature includes a solder ball. In some embodiments, forming the trench structure includes forming the trench structure circumferentially around the solder ball. In accordance with several embodiments, thinning down the encapsulating molding material includes removing the material of the at least one solder ball to more than half of its diameter.

In certain embodiments, the solder ball comprises a solder ball core enclosed by surrounding solder material. In various embodiments, the solder ball core is formed from a material different from the surrounding solder material. In some embodiments, the surrounding solder material includes a solder alloy. According to various embodiments, the solder alloy includes at least one of tin (Sn), copper (Cu), bismuth (Bi), indium (In), antimony (Sb), or silver (Ag). In several embodiments, the material of the solder ball core includes at least one of copper (Cu), nickel (Ni), silver (Ag), gold (Au), aluminum (Al), molybdenum (Mo), magnesium (Mg), zinc (Zn), cobalt (Co), or an alloy of any combination thereof.

In a number of embodiments, thinning down the encapsulating molding material involves at least one of grinding and milling.

According to certain embodiments, forming the trench structure includes controlled laser ablation of the material of the encapsulating molding material.

The present disclosure further relates in several aspects to a method of forming a dual-sided packaged radio-frequency (RF) module. The method comprises mounting at least one RF circuit component on a first surface of a packaging substrate and at least one circuitry component on a second surface of the packaging substrate opposite to the first surface. The method further comprises attaching at least one solder ball attached to the second surface of the packaging substrate, the vertical extension of the at least one solder ball being larger than the distance between the bottom surface of the at least one circuitry component and the second surface of the packaging substrate, the at least one solder ball including a solder ball core enclosed by surrounding solder material, the solder ball core being formed from a material different from the surrounding solder material. The method further comprises encapsulating the at least one solder ball and the at least one circuitry component with encapsulating molding material. The method further comprises thinning down the encapsulating molding material so that the material of the solder ball core is exposed from the bottom surface of the encapsulating molding material. The method further comprises re-forming the at least one solder ball by forming a cap of solder material on the portion of the solder ball core which is exposed from the bottom surface of the encapsulating molding material.

In some embodiments, the surrounding solder material includes a solder alloy. According to several embodiments, the solder alloy includes at least one of tin (Sn), copper (Cu), bismuth (Bi), indium (In), antimony (Sb), or silver (Ag). In a number of embodiments, the material of the solder ball core includes at least one of copper (Cu), nickel (Ni), silver (Ag), gold (Au), aluminum (Al), molybdenum (Mo), magnesium (Mg), zinc (Zn), cobalt (Co), or an alloy of any combination thereof.

In various embodiments, thinning down the encapsulating molding material involves at least one of grinding and milling. In some embodiments thinning down the encapsulating molding material includes removing the material of the solder ball core to more than half of its diameter.

### BRIEF DESCRIPTION OF THE DRAWINGS

Embodiments of this disclosure will now be described, by way of non-limiting example, with reference to the accompanying drawings.

FIG. 1 depicts a side sectional view of an example dual-sided module having a ball grid array (BGA) on its underside, according to some embodiments of the present disclosure;

FIG. 2 shows an example where the dual-sided BGA module of FIG. 1 is mounted on a circuit board, according to some embodiments of the present disclosure;

FIG. 3 depicts a side sectional view of an exemplary dual-sided packaged RF module having a ball grid array (BGA) on its underside, and mounted on a circuit board, according to some embodiments of the present disclosure;

FIGS. 4A to 4E show stages of an exemplary process for modelling an underside of the example dual-sided packaged RF module having the ball grid array (BGA) of FIG. 3, according to some embodiments of the present disclosure;

FIG. 5 depicts a side sectional view of a further exemplary dual-sided packaged RF module having a ball grid array (BGA) on its underside, and mounted on a circuit board, according to some embodiments of the present disclosure;

FIGS. 6A to 6D show stages of an exemplary process for modelling an underside of the example dual-sided packaged RF module having the ball grid array (BGA) of FIG. 5, according to some embodiments of the present disclosure;

FIG. 7 depicts a side sectional view of a further exemplary dual-sided packaged RF module having a ball grid array (BGA) on its underside, and mounted on a circuit board, according to some embodiments of the present disclosure;

FIGS. 8A to 8E show stages of a further exemplary process for modelling an underside of the example dual-sided packaged RF module having the ball grid array (BGA) of FIG. 7, according to some embodiments of the present disclosure;

FIG. 9 shows a dual-sided packaged RF module including a shielded package having one or more surface-mount technology (SMT) devices mounted on a packaging substrate, according to some embodiments of the present disclosure;

FIG. 10 shows a dual-sided packaged RF module that can be a more specific example of the dual-sided packaged RF module of FIG. 8, according to some embodiments of the present disclosure;

FIG. 11 shows a dual-sided packaged RF module that can be a more specific example of the dual-sided packaged RF module of FIG. 8, according to some embodiments of the present disclosure;

FIG. 12 shows an example of a radio-frequency (RF) module having one or more features as described herein, according to some embodiments of the present disclosure; and

FIG. 13 shows an example of a wireless device having one or more features as described herein, according to some embodiments of the present disclosure.

### DETAILED DESCRIPTION OF CERTAIN EMBODIMENTS

The headings provided herein, if any, are for convenience only and do not necessarily affect the scope or meaning of the claimed invention. The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

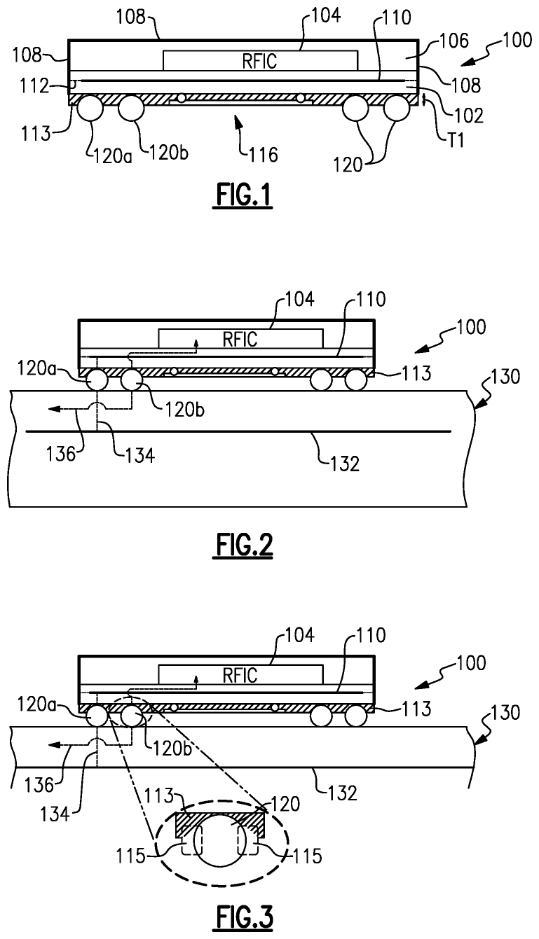

FIG. 1 depicts a side sectional view of an example of a dual-sided packaged RF module 100 having a ball grid array (BGA) on its underside. More particularly, the module 100 includes a packaging substrate 102 with a radio-frequency (RF) circuit (collectively indicated as 104) implemented on its first side (e.g., upper side), and one or more components (collectively indicated as 116) mounted on its second side (e.g., underside). The RF circuit 104 on the upper side of the packaging substrate 102 can include, for example, one or more semiconductor die, and/or one or more surface-mount technology (SMT) devices. The underside component(s) 116 can include, for example, one or more semiconductor die, and/or one or more SMT devices.

In the example module 100 of FIG. 1, an overmold 106 is shown to be implemented on the upper side of the packaging substrate 102 so as to encapsulate the RF circuit 104. Further, the upper surface of the overmold 106 and the side walls of the module 100 are shown to have a conductive layer 108 (e.g., a conformal conductive layer) that is electrically connected to a ground plane 110 within the packaging substrate 102 by a conductor 112. Accordingly, the conductive layer 108 and the ground plane 110 generally define an internal volume, and provide RF shielding functionality between the internal volume and external location(s). In some embodiments, the module 100 may or may not include additional shielding functionality (e.g., intra-module shielding between regions within the internal volume).

Although various examples are described herein in the context of modules having such shielding functionalities (e.g., conformal shielding and/or intra-module shielding), one or more features of the present disclosure can also be implemented in modules without such shielding functionalities.

In the example of FIG. 1, the BGA is shown to include a plurality of solder balls 120a, 120b and so on, generally referred to with 120. Such solder balls 120a, 120b, 120 are shown to be arranged so as to provide an underside volume dimensioned to allow mounting of the underside component(s) 116. Such underside component(s) 116 can be mounted to the underside of the packaging substrate 102 with or without an underfill.

Although various examples are described herein in the context of modules having such a BGA with solder balls, one or more features of the present disclosure can also be implemented in modules with other conductive structures as underside contact features. For example, pillars (e.g., columns, posts, etc.) can be utilized to provide functionalities similar to those of the solder balls.

FIG. 2 shows an example where the dual-sided packaged RF module 100 of FIG. 1 is mounted on a circuit board 130 (e.g., a phone board). Such a circuit board can be configured to include various electrical connections to facilitate various functionalities of the module 100. For example, a ground of the module 100 (e.g., at the ground plane 110) can be electrically connected to a ground of the circuit board 130 (e.g., at a ground plane 132) through an example solder ball 120a. Such an electrical connection is indicated as 134. In another example, a non-ground electrical connection can be made between the RF circuit 104 of the module 100 and another location (e.g., another module) associated with the circuit board 130, through an example solder ball 120b. Such an electrical connection is indicated as 136. In some embodiments, the non-ground electrical connection 136 can communicate, for example, power supply, control signals, and RF signals associated with operation of the module 100.

FIG. 3 shows a side sectional view of another example of a dual-sided packaged RF module 100 having a ball grid array (BGA) on its underside. More particularly, the module 100 includes a packaging substrate with a radio-frequency (RF) circuit implemented with various devices (collectively referred to as RFIC 104) such as one or more semiconductor die, and/or one or more surface-mount technology (SMT) devices. Such devices are shown to be implemented on a first side (e.g., upper side) of the packaging substrate. A second side (e.g., underside or bottom side) of the packaging substrate is shown to include one or more components such as a semiconductor die.

In the example module 100 of FIG. 3, an overmold is shown to be implemented on the upper side of the packaging substrate so as to encapsulate the various RFIC components 104. In the example module 100 of FIG. 3, the upper surface of the overmold and the side walls of the module 100 may or may not have a conductive layer (e.g., a conformal conductive layer) that is electrically connected to a ground plane within the packaging substrate. Such a conductive layer and the ground plane generally define an internal volume, and provide RF shielding functionality between the internal volume and external location(s). In some embodiments, the module 100 may or may not include additional shielding functionality (e.g., intra-module shielding between regions within the internal volume).

Although various examples are described herein in the context of modules having such shielding functionalities (e.g., conformal shielding and/or intra-module shielding), one or more features of the present disclosure can also be implemented in modules without such shielding functionalities.

In the example of FIGS. 1 to 3, the BGA is shown to include a plurality of solder balls 120. Such solder balls are shown to be arranged so as to provide an underside volume dimensioned to allow mounting of the underside component(s) 116. Such underside component(s) can be mounted to the underside of the packaging substrate 102 with one or more underside solder balls, an underfill and/or similar mounting elements.

In some embodiments, each of the module 100 of FIG. 1, the module 100 of FIG. 2 and the module 100 of FIG. 3 can include an underside molding. In the example of FIGS. 1, 2, and 3, such an underside molding is indicated as 113.

In the example of FIGS. 2 and 3, the underside molding 113 is depicted as being implemented between the underside of the module 100 and a circuit board 130 (e.g., a phone board) on which the module 100 is mounted. In some embodiments, the underside molding 113 can be implemented on the underside of the packaging substrate 102. In such embodiments, the underside molding 113 are part of an unmounted module 100.

In some embodiments, the underside molding 113 on the underside of the shielded package may provide for a more secure mounting of the lower component(s) 116. In some embodiments, the underside molding 113 on the underside of the shielded package may provide for additional shielding of the lower component(s) 116.

The example of a dual-sided packaged RF module 100 shows one or more lower components 116 that can be mounted under a shielded package, generally within a volume defined on an underside of the shielded package. In some embodiments, a set of through-mold connections (e.g., one or more through-mold connections) may be implemented, formed, located, and/or positioned on the underside (e.g., the bottom side as illustrated in FIGS. 1, 2, and 3) of the shielded package. The set of through-mold connections may define a volume on the underside of the shielded package. A volume under a shielded package is shown to be defined by the underside of the shielded package and solder balls 120 of a ball grid array (BGA). The BGA may be a set of through-mold connections. For example, each solder ball 120 of the BGA may be a through-mold connection in the set of through-mold connections. Other examples of through-mold connections include, but are not limited to solder balls, pillars, columns, posts, pedestals, etc.

The through-mold connections described herein may also be referred to as contact features. The contact features (e.g., the solder balls 120) allow the dual-sided packaged RF module 100 to be mounted on a circuit board such as a phone board 130. The contact features can be configured so that when mounted to the circuit board 130, there is sufficient vertical space between the upper surface of the circuit 130 and the lower surface of the shielded package for the lower component 116. The volume can be at least partially filled with an underside molding 113, for example up to a thickness T1, exemplarily indicated in FIG. 1. The thickness T1 may in particular be less than the thickness of the contact features, i.e., the diameter of the solder balls 120 in FIGS. 1, 2, and 3. In FIGS. 2 and 3, the thickness T1 is in particular less than the distance between the bottom side of the packaging substrate 102 and the upper side of the circuit board 130. The thickness T1 of the underside molding may in some embodiments be less than half of the thickness of the contact features, i.e., less than half the diameter of the solder balls in FIGS. 1, 2, and 3. This may aid in properly re-building the solder balls 120 after removal of the material of the underside molding during manufacturing the dual-sided packaged RF module 100. The underside molding 113 substantially encapsulates the lower component 116. In certain embodiments, at least a portion of the contact features (e.g., the solder balls 120) may be exposed through the underside molding 113. Exposing at least a portion of the solder balls 120 may provide a connection (e.g., an electrical and/or thermal connection) through the underside molding 113. For example, the solder balls 120 may provide a connection (e.g., an electrical connection) to the lower component 116 and/or upper components 104 in the shielded package. In various embodiments, solder (or other conductive material) may be applied to the exposed portion of the solder balls 120 to form a connection (e.g., electrical connection) with the circuit board 130. In some embodiments, the underside molding 113 may be formed together with the solder balls 120 (e.g., the exposed portions of the solder balls 120) in a land grid array (LGA) type/style package.

The electrical connection between the dual-sided packaged RF module 100 and the circuit board 130 may be facilitate by solder material from the contact features that is deposited/melted onto pads of the circuit board 130 when the dual-sided packaged RF module 100 is attached to the circuit board 130. For example, during a reflow process, heat may be applied to melt at least a portion of a contact feature, such as the solder ball(s) 120, to form the solder material. The solder material may also include additional material that is formed, implemented, deposited, etc., over the solder ball 120. The pad(s) may provide electrical and/or thermal conductivity between the dual-sided packaged RF module 100 and other components/circuits attached to the circuit board 130 (not illustrated in the figures). In some embodiments, the pad may include solder material as well.

The underside molding 113 may have a surface facing downward towards the circuit board 130. In some embodiments, this surface is not in physical contact with the upper surface of the circuit board 130 so that a gap is present between the two adjacent surfaces. Such a gap may in some embodiments aid in protecting the lower component(s) 116 from mechanical damage due to linear displacements of the dual-sided packaged RF module 100, for example, flexing, concussions or other mechanical shocks which may be a consequence of dropping the circuit board 130. The portion of the underside molding 113 that adheres to the sides of the lower component(s) 116 may provide additional protection from damage due to linear displacements of the dual-sided packaged RF module 100, for example, flexing, concussions or other mechanical shocks which may be a consequence of dropping the circuit board 130. In some embodiments, the gap between the bottom surface of the underside molding 113 and the upper surface of the circuit board 130 may also allow the dual-sided packaged RF module 100 to adapt to process/manufacturing variations when the dual-sided packaged RF module 100 is installed on the circuit board 130. For example, different temperatures may be used to melt the solder ball 120 during installation of the dual-sided packaged RF module 100. The gap may help ensure that the dual-sided packaged RF module 100 is properly installed by providing enough distance between the bottom surface of the underside molding 113 and the upper surface of the circuit board 130 while still allowing the solder material of the solder ball(s) 120 to properly bond with the respective pad(s) of the circuit board 130 to which an electrical connection is to be formed.

A close-up view of the surrounding of a contact feature, e.g., a solder ball 120, is also illustrated in FIG. 3. As illustrated in the close-up view, the solder ball 120 is surrounded by a trench structure 115 formed in the underside molding 113. The trench structure 115 may, for example, be a circumferentially closed recess or indentation in the material of the underside molding 113. The trench structure 115 may, for example, be formed by targeted removal of the material of the underside molding 113 after the underside molding 113 has been applied to the bottom side of the packaging substrate 102. Moreover, in some embodiments the bottom side of the underside molding 113 may be flush with the bottom side of the one or more lower components 116. In those configurations, the opening of the trench structure 115 may be flush with the bottom side of the lower component(s) 116 as well, and therefore the depth of the trench structure 115 may reach beyond the plane of the bottom side of the lower component(s) 116. In other words, the distance between the depth of the trench structure 115 and the bottom side of the packaging substrate 102 is less than the distance T1 between the bottom side of the lower component(s) 116 and the bottom side of the packaging substrate 102. More specifically, the distance T1 between the bottom side of the lower component(s) 116 and the bottom side of the packaging substrate may in some embodiments be less than half of the thickness of the solder balls 120.

The trench structure 115 may, for example, be recesses of triangular or trapezoidal cross-section running around the edges of the solder balls 120 that are exposed from the underside molding 113. The width of the recesses of the trench structure 115 may gradually decrease when followed from the surface of the underside molding 113 towards the bottom side of the packaging substrate 102.

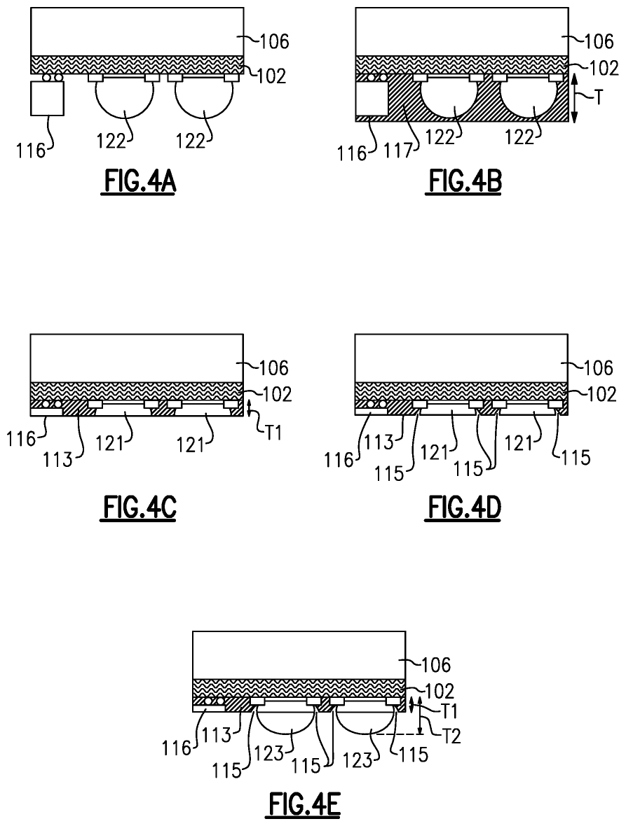

The dual-sided packaged RF module 100 may be installed on the circuit board 130 using the solder balls 120a, 120b, 120. The solder balls 120 may be attached to the circuit board 130 (by e.g., installation, mounting, fixing, or other means). As illustrated in the close-up view of the solder ball 120, the solder ball 120 is at least partially embedded in the underside molding 113, surrounded by the respective trench structure 115. The solder ball 120 may be formed in a process that involves mounting an initial or preliminary solder ball, creating the underside molding 113 around the initial or preliminary solder ball as well as over the lower component(s) 116, thinning the underside molding 113 along with part of the initial or preliminary solder ball and part of the lower component(s) 116 down to a thickness that is lower than the diameter of the initial or preliminary solder ball, and at least partially reforming the thinned down solder ball by forming a solder cap on the underside of the thinned down solder ball. Specifically, thinning down the underside molding 113 may be performed down to a thickness where more than half of the initial or preliminary solder ball is removed as well. In the thinning process, the lower component(s) 116 is/are ground down to a thickness that is lower than the initial thickness of the component(s) after mounting. Thereby, the reforming the thinned down solder ball by forming a solder cap is facilitated. An exemplary process for forming a ball grid array (BGA) at the bottom side of the dual-sided packaged RF module 100 will be discussed in conjunction with the illustrations of FIGS. 4A to 4E.

As shown in FIG. 4A, for manufacturing a dual-sided packaged RF module according to some embodiments, a packaging substrate 102 may be provided with an overmold 106 on its upper side. The overmold 106 may, for example, encapsulate various RFIC components, such as the RFIC components 104 of FIG. 1, 2, or 3, arranged or mounted on the upper side of the packaging substrate 102. One or more lower components 116 may be mounted on the bottom side of the packaging substrate 102, i.e., on the surface that is opposite to the surface of the packaging substrate 102 on which the overmold 106 is formed. A number of initial or preliminary solder balls 122 are formed on the bottom side of the packaging substrate 102.

As shown in FIG. 4B, the lower component(s) 116 and the initial or preliminary solder balls 122 are overmolded with an encapsulating molding material 117. The encapsulating molding material 117 covers the lower component(s) 116 and the initial or preliminary solder balls 122 entirely. The thickness T of the encapsulating molding material 117, i.e., the distance between the bottom side of the packaging substrate 102 and the bottom surface of the encapsulating molding material 117, may be selected to be larger than the largest vertical extension of the lower component(s) 116 and the initial or preliminary solder balls 122 perpendicular to the bottom surface of the packaging substrate 102. As exemplarily shown in FIGS. 4A and 4B, the vertical extension of the initial or preliminary solder balls 122 is larger than the vertical extension of the lower component(s) 116.

As shown in FIG. 4C, the encapsulating molding material 117 is then thinned down, for example, by grinding, milling or otherwise skimming layers of molding material 117 from the bottom surface of the encapsulating molding material 117. The process of thinning down the encapsulating molding material 117 may in some embodiments be performed until a portion of the initial or preliminary solder balls 122 is ablated so that the material of the initial or preliminary solder balls 122 shows through the bottom surface of the encapsulating molding material 117. Specifically, the process of thinning down the encapsulating molding material 117 may in some embodiments be performed until more than half of the diameter of the initial or preliminary solder balls 122 is ablated. In some embodiments, the process of thinning down the encapsulating molding material 117 may be stopped before the lower components 116 are exposed from the encapsulating molding material 117. In some embodiments, the lower component 116 is milled or ground down to a thickness that is lower than the initial thickness of the component(s) after mounting. That is, the process of thinning down the encapsulating molding material 117 may be continued until a portion of the lower components 116 is exposed from the encapsulating molding material 117. In some embodiments, the process of thinning down the encapsulating molding material 117 may be continued until not only a portion of the lower components 116 is exposed from the encapsulating molding material 117, but a portion of the lower components 116 is removed during the grinding or milling process as well along with the removal of the encapsulating molding material 117.

Further referring to FIG. 4C, after the process of thinning down the encapsulating molding material has been stopped, the thinned down portion of the encapsulating molding material will form the underside molding 113. The underside molding 113 will have a thickness T1, i.e., a vertical extension from the bottom surface of the packaging substrate 102 that is smaller than the initial thickness T of the encapsulating molding material 117. In particular, the thickness T1 of the underside molding 113 may be smaller than the largest vertical extension of the lower component(s) 116 and the initial or preliminary solder balls 122 perpendicular to the bottom surface of the packaging substrate 102. As shown in FIG. 4C, the portion of the initial or preliminary solder balls 122 that remains after the process of thinning down the encapsulating molding material 117 are partially cut-away spheres 121, the circles of the partially cut-away spheres 121 being flush with the bottom surface of the underside molding 113.

As shown in FIG. 4D, a trench structure 115 is then formed in the molding material of the underside molding 113. The trench structure 115 is formed around the perimeter of the partially cut-away spheres 121 of the solder balls. The trench structure 115 may, for example, be formed by targeted removal of the material of the underside molding 113, such as, for example, by controlled laser ablation, after the underside molding 113 has been applied to the bottom side of the packaging substrate 102. The opening of the trench structure 115 may be flush with the bottom side of the lower component(s) 116 as well, and therefore the depth of the trench structure 115 may reach beyond the plane of the bottom side of the lower component(s) 116. The trench structure 115 may, for example, be recesses of triangular or trapezoidal cross-section running around the edges of the partially cut-away spheres 121 of the solder balls that are exposed from the underside molding 113. The width of the recesses of the trench structure 115 may gradually decrease when followed from the surface of the underside molding 113 towards the bottom surface of the packaging substrate 102. The trench structure 115 may in some embodiments be formed around all of the partially cut-away spheres 121 of the solder balls. The trench structure 115 may in some embodiments be formed around only a select portion of the partially cut-away spheres 121 of the solder balls.

As shown in FIG. 4E, after formation of the trench structure 115, the solder balls may be re-formed in a post-ablation process. To that end, a cap 123 of solder material may be formed on the partially cut-away spheres 121 of the solder balls. For example, additional solder material may be paste printed on top of the solder material already exposed from the surface of the underside molding 113. The additional solder material may, for example, be solder paste, such as powdered solder material in a flux paste. The solder paste may be applied to the partially cut-away spheres 121 of the solder balls by a stencil-printing process, a pin transfer process, or a jet printing process. After the disposal of the additional solder material, the solder caps 123 may be reflown and washed. In some embodiments, the solder caps 123 may be plasma-treated after reflowing and washing. Together with the remaining solder material of the initial or preliminary solder balls 122, the appropriately treated solder caps 123 may form the re-formed solder balls, such as the solder balls 120a, 120b, and/or 120 as illustrated and explained in conjunction with FIGS. 1, 2, and 3. The diameter T2 of the re-formed solder balls may be larger than the thickness T1 of the underside molding 113 so that the re-formed solder balls will create a gap or standoff between the bottom surface of the underside molding 113 and a surface of a circuit board on which the dual-sided packaged RF module is placed.

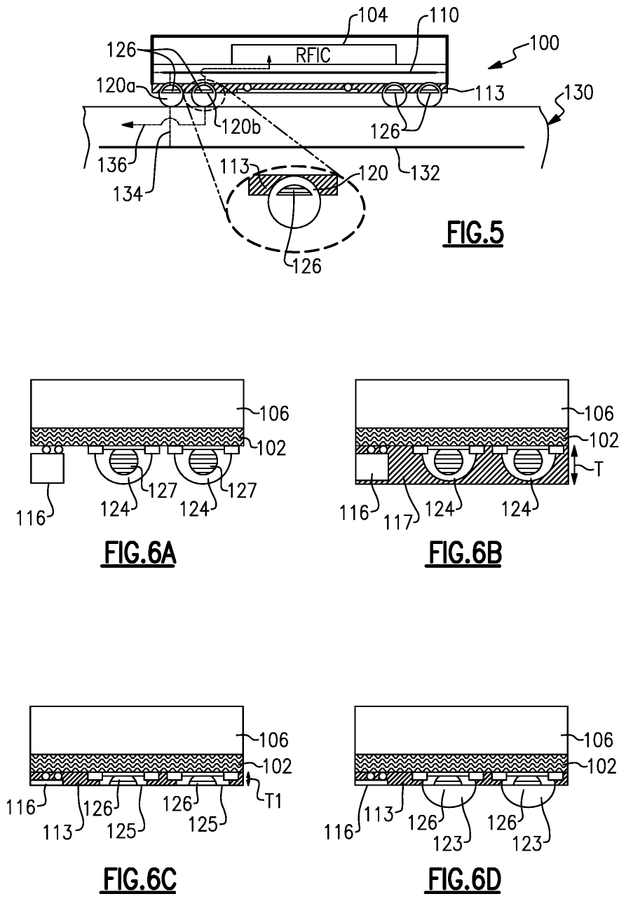

FIG. 5 shows a side sectional view of a further example of a dual-sided packaged RF module 100 having a ball grid array (BGA) on its underside. More particularly, the module 100 includes a packaging substrate with a radio-frequency (RF) circuit implemented with various devices (collectively referred to as RFIC 104) such as one or more semiconductor die, and/or one or more surface-mount technology (SMT) devices. Such devices are shown to be implemented on a first side (e.g., upper side) of the packaging substrate. A second side (e.g., underside or bottom side) of the packaging substrate is shown to include one or more components such as a semiconductor die.

The dual-sided packaged RF module 100 of FIG. 5 is similar to the dual-sided packaged RF module 100 of FIG. 2 except that the solder balls 120 are formed with a solder ball core 126. The solder ball core 126 is formed from a material that is different from the surrounding solder material of the solder ball 120. For example, the surrounding solder material of the solder ball may be a solder alloy. The solder alloy of the surrounding solder material may in some embodiments contain tin (Sn), copper (Cu), bismuth (Bi), indium (In), antimony (Sb), and/or silver (Ag) in variable relative amounts. The solder ball core 126 may in some embodiments be formed from copper (Cu), nickel (Ni), silver (Ag), gold (Au), aluminum (Al), molybdenum (Mo), magnesium (Mg), zinc (Zn), cobalt (Co), or from an alloy of any combination of those metals.

Similar to the dual-sided packaged RF module 100 of FIG. 2, the dual-sided packaged RF module 100 of FIG. 5 may be installed on a circuit board 130 using the solder balls 120a, 120b, 120 with a partially cut-away solder core 126. The solder balls 120 may be attached to the circuit board 130 (by e.g., installation, mounting, fixing, or other means). The solder ball 120 may be formed in a process that involves mounting an initial or preliminary solder ball with a solder core 126, creating the underside molding 113 around the initial or preliminary solder ball as well as over the lower component(s) 116, thinning the underside molding 113 along with part of the initial or preliminary solder ball and part of the lower component(s) 116 down to a thickness that is lower than the diameter of the initial or preliminary solder ball, and at least partially reforming the thinned down solder ball by forming a solder cap of solder material on the underside of the thinned down solder ball. In particular, the process of thinning the underside molding 113 along with part of the initial or preliminary solder ball involves ablating layers of the surrounding solder material as well as a portion of the solder core 126. In the thinning process, the lower component(s) 116 is/are ground down to a thickness that is lower than the initial thickness of the component(s) after mounting. The underside molding 113 may in some embodiments be ablated so that more than half of the diameter of the solder core 126 is ablated as well. This may aid in properly re-building the solder balls 120a, 120b, 120 after removal of the material of the underside molding 113 during manufacturing the dual-sided packaged RF module 100. A first exemplary process for forming a ball grid array (BGA) at the bottom side of the dual-sided packaged RF module 100 of FIG. 5 will be discussed in conjunction with the illustrations of FIGS. 6A to 6D.

As shown in FIG. 6A, for manufacturing a dual-sided packaged RF module according to some embodiments, a packaging substrate 102 may be provided with an overmold 106 on its upper side. The overmold 106 may, for example, encapsulate various RFIC components, such as the RFIC components 104 of FIG. 5, arranged or mounted on the upper side of the packaging substrate 102. One or more lower components 116 may be mounted on the bottom side of the packaging substrate 102, i.e., on the surface that is opposite to the surface of the packaging substrate 102 on which the overmold 106 is formed. A number of initial or preliminary solder balls 124 are formed on the bottom side of the packaging substrate 102. The initial or preliminary solder balls 124 are formed with a preliminary solder ball core 127. The preliminary solder ball core 127 is formed from a material that is different from the surrounding solder material of the initial or preliminary solder ball 124. For example, the surrounding solder material of the solder ball may be a solder alloy. The solder alloy of the surrounding solder material may in some embodiments contain tin (Sn), copper (Cu), bismuth (Bi), indium (In), antimony (Sb), and/or silver (Ag) in variable relative amounts. The preliminary solder ball core 127 may in some embodiments be formed from copper (Cu), nickel (Ni), silver (Ag), gold (Au), aluminum (Al), molybdenum (Mo), magnesium (Mg), zinc (Zn), cobalt (Co), or from an alloy of any combination of those metals.

As shown in FIG. 6B, the lower component(s) 116 and the initial or preliminary solder balls 124 with the preliminary solder core 127 are overmolded with an encapsulating molding material 117. The encapsulating molding material 117 covers the lower component(s) 116 and the initial or preliminary solder balls 124 entirely. The thickness T of the encapsulating molding material 117, i.e., the distance between the bottom side of the packaging substrate 102 and the bottom surface of the encapsulating molding material 117, may be selected to be larger than the largest vertical extension of the lower component(s) 116 and the initial or preliminary solder balls 124 perpendicular to the bottom surface of the packaging substrate 102. As exemplarily shown in FIGS. 6A and 6B, the vertical extension of the initial or preliminary solder balls 124 is larger than the vertical extension of the lower component(s) 116.

As shown in FIG. 6C, the encapsulating molding material 117 is then thinned down, for example, by grinding, milling or otherwise skimming layers of molding material 117 from the bottom surface of the encapsulating molding material 117. The process of thinning down the encapsulating molding material 117 may in some embodiments be performed until a portion of the initial or preliminary solder balls 124 as well as a portion of the preliminary solder ball core 127 is ablated so that the material of the initial or preliminary solder balls 124 and the preliminary solder ball core 127 shows through the bottom surface of the encapsulating molding material 117. Specifically, the process of thinning down the encapsulating molding material 117 may in some embodiments be performed until more than half of the diameters of the initial or preliminary solder balls 124 and the preliminary solder ball cores 127 are ablated. In some embodiments, the process of thinning down the encapsulating molding material 117 may be stopped before the lower components 116 are exposed from the encapsulating molding material 117. In some embodiments, the lower component 116 is milled or ground down to a thickness that is lower than the initial thickness of the component(s) after mounting. That is, the process of thinning down the encapsulating molding material 117 may be continued until a portion of the lower components 116 is exposed from the encapsulating molding material 117. In some embodiments, the process of thinning down the encapsulating molding material 117 may be continued until not only a portion of the lower components 116 is exposed from the encapsulating molding material 117, but a portion of the lower components 116 is removed during the grinding or milling process as well along with the removal of the encapsulating molding material 117.

Further referring to FIG. 6C, after the process of thinning down the encapsulating molding material has been stopped, the thinned down portion of the encapsulating molding material will form the underside molding 113. The underside molding 113 will have a thickness T1, i.e., a vertical extension from the bottom surface of the packaging substrate 102 that is smaller than the initial thickness T of the encapsulating molding material 117. In particular, the thickness T1 of the underside molding 113 may be smaller than the largest vertical extension of the lower component(s) 116 and the initial or preliminary solder balls 124 perpendicular to the bottom surface of the packaging substrate 102. As shown in FIG. 6C, the portions of the initial or preliminary solder balls 124 that remain after the process of thinning down the encapsulating molding material 117 are partially cut-away spheres 125, the circles of the partially cut-away spheres 125 being flush with the bottom surface of the underside molding 113.

As shown in FIG. 6D, after the thinning process of FIG. 6C, the solder balls may be re-formed in a post-ablation process. To that end, a cap 123 of solder material may be formed on the partially cut-away spheres 125 of the solder balls. For example, additional solder material may be paste printed on top of the solder material already exposed from the surface of the underside molding 113. The additional solder material may, for example, be solder paste, such as powdered solder material in a flux paste. The solder paste may be applied to the partially cut-away spheres 125 of the solder balls by a stencil-printing process, a pin transfer process, or a jet printing process. After the disposal of the additional solder material, the solder caps 123 may be reflown and washed. In some embodiments, the solder caps 123 may be plasma-treated after reflowing and washing. Together with the remaining solder material of the initial or preliminary solder balls 124 and the core material of the cut-away solder core 126, the appropriately treated solder caps 123 may form the re-formed solder balls, such as the solder balls 120a, 120b, and/or 120 as illustrated and explained in conjunction with FIGS. 2 and 5. The diameters of the re-formed solder balls may be larger than the thickness T1 of the underside molding 113 so that the re-formed solder balls will create a gap or standoff between the bottom surface of the underside molding 113 and a surface of a circuit board on which the dual-sided packaged RF module is placed.

FIG. 7 shows a side sectional view of a further example of a dual-sided packaged RF module 100 having a ball grid array (BGA) on its underside. More particularly, the module 100 includes a packaging substrate with a radio-frequency (RF) circuit implemented with various devices (collectively referred to as RFIC 104) such as one or more semiconductor die, and/or one or more surface-mount technology (SMT) devices. Such devices are shown to be implemented on a first side (e.g., upper side) of the packaging substrate. A second side (e.g., underside or bottom side) of the packaging substrate is shown to include one or more components such as a semiconductor die.

The dual-sided packaged RF module 100 of FIG. 7 is similar to the dual-sided packaged RF module 100 of FIG. 3 except that the solder balls 120 are formed with a solder ball core 126. The solder ball core 126 is formed from a material that is different from the surrounding solder material of the solder ball 120. For example, the surrounding solder material of the solder ball may be a solder alloy. The solder alloy of the surrounding solder material may in some embodiments contain tin (Sn), copper (Cu), bismuth (Bi), indium (In), antimony (Sb), and/or silver (Ag) in variable relative amounts. The solder ball core 126 may in some embodiments be formed from copper (Cu), nickel (Ni), silver (Ag), gold (Au), aluminum (Al), molybdenum (Mo), magnesium (Mg), zinc (Zn), cobalt (Co), or from an alloy of any combination of those metals.

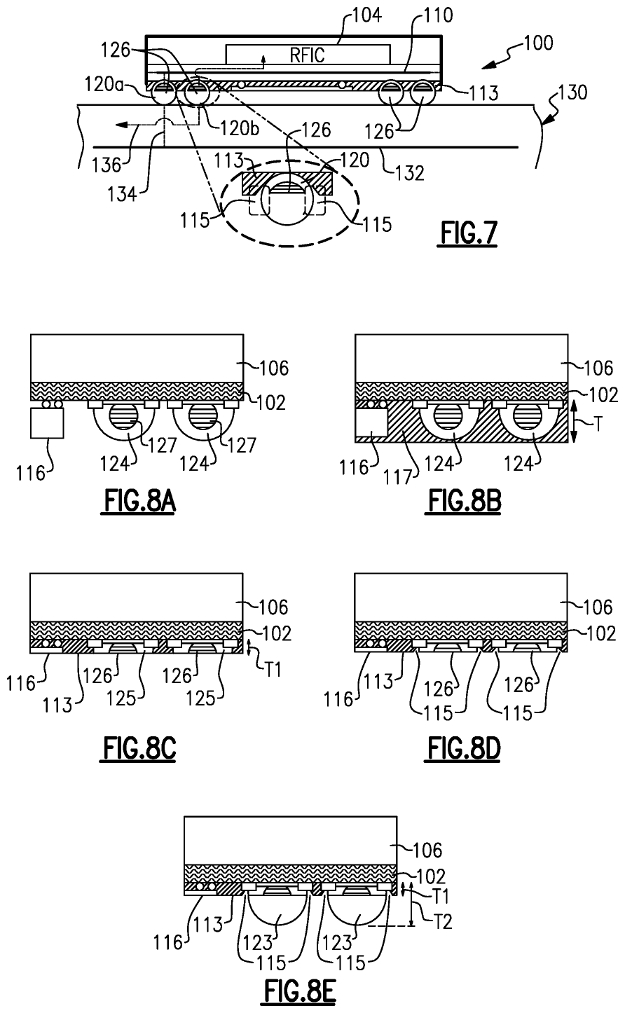

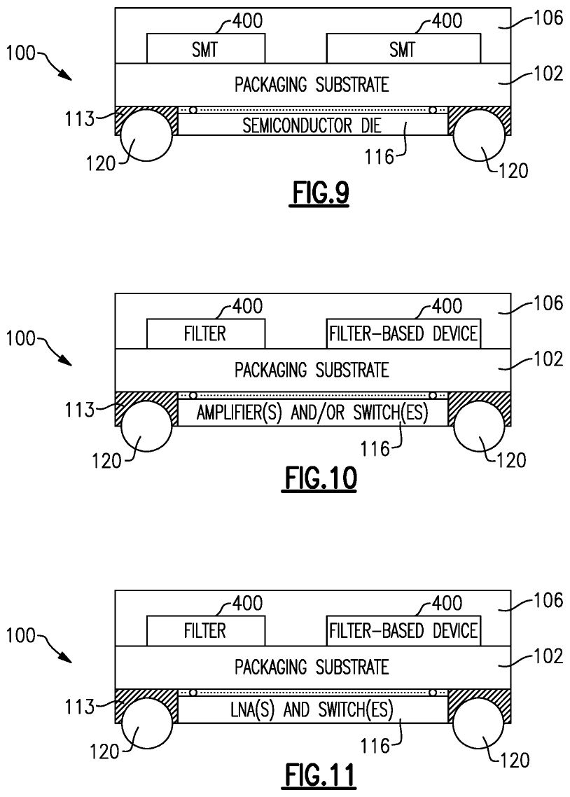

Similar to the dual-sided packaged RF module 100 of FIG. 3, the dual-sided packaged RF module 100 of FIG. 7 may be installed on a circuit board 130 using the solder balls 120a, 120b, 120 with the solder cores 126. The solder balls 120 may be attached to the circuit board 130 (by e.g., installation, mounting, fixing or other means). As illustrated in the close-up view of the solder ball 120, the solder ball 120 is at least partially embedded in the underside molding 113, surrounded by the respective trench structure 115. The solder ball 120 may be formed in a process that involves mounting an initial or preliminary solder ball with a preliminary solder core 127, creating the underside molding 113 around the initial or preliminary solder ball as well as over the lower component(s), thinning the underside molding 113 along with part of the initial or preliminary solder ball and part of the lower component(s) down to a thickness that is lower than the diameter of the initial or preliminary solder ball, and at least partially reforming the thinned down solder ball by forming a solder cap of solder material on the underside of the thinned down solder ball. In particular, the process of thinning the underside molding 113 along with part of the initial or preliminary solder ball involves ablating layers of the surrounding solder material as well as a portion of the preliminary solder core 127. In the thinning process, the lower component(s) is/are ground down to a thickness that is lower than the initial thickness of the component(s) after mounting. A second exemplary process for forming a ball grid array (BGA) at the bottom side of the dual-sided packaged RF module 100 of FIG. 7 will be discussed in conjunction with the illustrations of FIGS. 8A to 8E.

As shown in FIG. 8A, for manufacturing a dual-sided packaged RF module according to some embodiments, a packaging substrate 102 may be provided with an overmold 106 on its upper side. The overmold 106 may, for example, encapsulate various RFIC components, such as the RFIC components 104 of FIG. 3 or 7, arranged or mounted on the upper side of the packaging substrate 102. One or more lower components 116 may be mounted on the bottom side of the packaging substrate 102, i.e., on the surface that is opposite to the surface of the packaging substrate 102 on which the overmold 106 is formed. A number of initial or preliminary solder balls 124 are formed on the bottom side of the packaging substrate 102. The initial or preliminary solder balls 124 are formed with a preliminary solder ball core 127. The preliminary solder ball core 127 is formed from a material that is different from the surrounding solder material of the initial or preliminary solder ball 124. For example, the surrounding solder material of the solder ball may be a solder alloy. The solder alloy of the surrounding solder material may in some embodiments contain tin (Sn), copper (Cu), bismuth (Bi), indium (In), antimony (Sb), and/or silver (Ag) in variable relative amounts. The preliminary solder ball core 127 may in some embodiments be formed from copper (Cu), nickel (Ni), silver (Ag), gold (Au), aluminum (Al), molybdenum (Mo), magnesium (Mg), zinc (Zn), cobalt (Co), or from an alloy of any combination of those metals.

As shown in FIG. 8B, the lower component(s) 116 and the initial or preliminary solder balls 124 with the preliminary solder cores 127 are overmolded with an encapsulating molding material 117. The encapsulating molding material 117 covers the lower component(s) 116 and the initial or preliminary solder balls 124 entirely. The thickness T of the encapsulating molding material 117, i.e., the distance between the bottom side of the packaging substrate 102 and the bottom surface of the encapsulating molding material 117, may be selected to be larger than the largest vertical extension of the lower component(s) 116 and the initial or preliminary solder balls 124 perpendicular to the bottom surface of the packaging substrate 102. As exemplarily shown in FIGS. 8A and 8B, the vertical extension of the initial or preliminary solder balls 124 is larger than the vertical extension of the lower component(s) 116.

As shown in FIG. 8C, the encapsulating molding material 117 is then thinned down, for example, by grinding, milling, or otherwise skimming layers of molding material 117 from the bottom surface of the encapsulating molding material 117. The process of thinning down the encapsulating molding material 117 may in some embodiments be performed until a portion of the initial or preliminary solder balls 124 as well as a portion of the preliminary solder ball cores 127 are ablated so that the material of the initial or preliminary solder balls 124 and the preliminary solder ball cores 127 shows through the bottom surface of the encapsulating molding material 117. Specifically, the process of thinning down the encapsulating molding material 117 may in some embodiments be performed until more than half of the diameter initial or preliminary solder balls 124 and the preliminary solder ball cores 127 are ablated. In some embodiments, the process of thinning down the encapsulating molding material 117 may be stopped before the lower components 116 are exposed from the encapsulating molding material 117. In some embodiments, the lower component 116 is milled or ground down to a thickness that is lower than the initial thickness of the component(s) after mounting. That is, the process of thinning down the encapsulating molding material 117 may be continued until a portion of the lower components 116 is exposed from the encapsulating molding material 117. In some embodiments, the process of thinning down the encapsulating molding material 117 may be continued until not only a portion of the lower components 116 is exposed from the encapsulating molding material 117, but a portion of the lower components 116 is removed during the grinding or milling process as well along with the removal of the encapsulating molding material 117.

Further referring to FIG. 8C, after the process of thinning down the encapsulating molding material has been stopped, the thinned down portion of the encapsulating molding material will form the underside molding 113. The underside molding 113 will have a thickness T1, i.e., a vertical extension from the bottom surface of the packaging substrate 102 that is smaller than the initial thickness T of the encapsulating molding material 117. In particular, the thickness T1 of the underside molding 113 may be smaller than the largest vertical extension of the lower component(s) 116 and the initial or preliminary solder balls 124 perpendicular to the bottom surface of the packaging substrate 102. As shown in FIG. 8C, the portions of the initial or preliminary solder balls 124 that remain after the process of thinning down the encapsulating molding material 117 are partially cut-away spheres 125, the circles of the partially cut-away spheres 125 being flush with the bottom surface of the underside molding 113.

As shown in FIG. 8D, a trench structure 115 is then formed in the molding material of the underside molding 113. The trench structure 115 is formed around the perimeter of the partially cut-away spheres 125 of the solder balls. The trench structure 115 may, for example, be formed by targeted removal of the material of the underside molding 113, such as, for example, by controlled laser ablation, after the underside molding 113 has been applied to the bottom side of the packaging substrate 102. The opening of the trench structure 115 may be flush with the bottom side of the lower component(s) 116 as well, and therefore the depth of the trench structure 115 may reach beyond the plane of the bottom side of the lower component(s) 116. The trench structure 115 may, for example, be recesses of triangular or trapezoidal cross-section running around the edges of the partially cut-away spheres 125 of the solder balls that are exposed from the underside molding 113. The widths of the recesses of the trench structure 115 may gradually decrease when followed from the surface of the underside molding 113 towards the bottom surface of the packaging substrate 102. The trench structure 115 may in some embodiments be formed around all of the partially cut-away spheres 125 of the solder balls. The trench structure 115 may in some embodiments be formed around only a select portion of the partially cut-away spheres 125 of the solder balls.

As shown in FIG. 8E, after formation of the trench structure(s) 115, the solder balls may be re-formed in a post-ablation process. To that end, a cap 123 of solder material may be formed on the partially cut-away spheres 125 of the solder balls. For example, additional solder material may be paste printed on top of the solder material already exposed from the surface of the underside molding 113. The additional solder material may, for example, be solder paste, such as powdered solder material in a flux paste. The solder paste may be applied to the partially cut-away spheres 125 of the solder balls by a stencil-printing process, a pin transfer process, or a jet printing process. After the disposal of the additional solder material, the solder caps 123 may be reflown and washed. In some embodiments, the solder caps 123 may be plasma-treated after reflowing and washing. Together with the remaining solder material of the initial or preliminary solder balls 124 and the core material of the cut-away solder core 126, the appropriately treated solder caps 123 may form the re-formed solder balls, such as the solder balls 120a, 120b, and/or 120 as illustrated and explained in conjunction with FIGS. 2 and 5. The diameter T2 of the re-formed solder balls may be larger than the thickness T1 of the underside molding 113 so that the re-formed solder balls will create a gap or standoff between the bottom surface of the underside molding 113 and a surface of a circuit board on which the dual-sided packaged RF module is placed.

Examples of Products Related to Dual-Sided Packaged RF Modules

As described herein, a shielded package and a lower component of a dual-sided packaged RF module can include different combinations of components. FIG. 9 shows that in some embodiments, a dual-sided packaged RF module 100 can include a shielded package having one or more surface-mount technology (SMT) devices 400 mounted on a packaging substrate 102. As further shown in FIG. 9, one or more semiconductor die 116 can be mounted under the packaging substrate 102. As described herein, the one or more die can be mounted within a region generally defined by an array of contact features, for example, solder balls 120.

As further described herein, an overmold 106 can be formed over the packaging substrate 102 so as to substantially encapsulate the SMT device(s) 400, and to facilitate shielding functionalities. It will be understood that the shielded packaged module can include one or more shielding features as described herein.

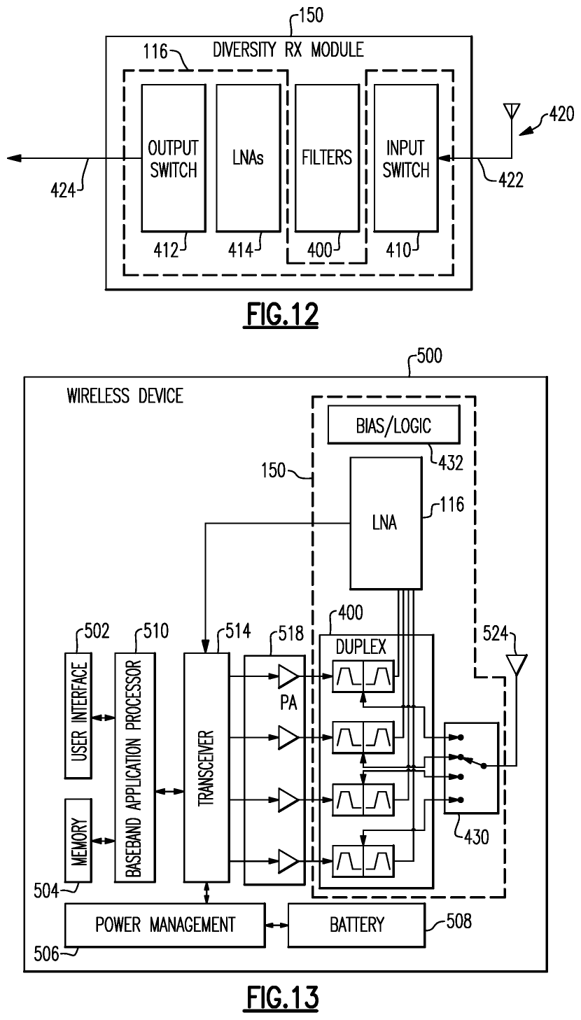

FIG. 10 shows a dual-sided packaged RF module 100 that can be a more specific example of the dual-sided packaged RF module 100 of FIG. 9. In the example of FIG. 10, the SMT device(s) 400 can be one or more filters and/or filter-based devices 400 that are encapsulated by an overmold 106. Further, the semiconductor die mounted under a packaging substrate 102 can be a die having RF amplifier(s) and/or switch(es). Accordingly, such a dual-side package can be implemented as different modules configured to facilitate transmission and/or reception of RF signals. For example, the dual-sided packaged RF module 100 can be implemented as a power amplifier (PA) module, a low-noise amplifier (LNA) module, a front-end module (FEM), a switching module, etc.

FIG. 11 shows a dual-sided packaged RF module 100 that can be a more specific example of the dual-sided packaged RF module of FIG. 9. In the example of FIG. 11, the semiconductor die mounted under a packaging substrate 102 can be a die having one or more LNAs and one or more switches. In some embodiments, such a dual-sided packaged RF module can be implemented as a module having LNA-related functionalities, including, for example, an LNA module.

In some implementations, a packaged module having one or more features as described herein can be utilized in various products. For example, FIGS. 12 and 13 show examples of how a packaged module having one or more features as described herein can be configured for use in a wireless device, and/or be implemented in a wireless device. FIG. 12 shows that in some embodiments, a packaged module having one or more features as described herein can be implemented as a diversity receive (RX) module 150. In some applications, such a module can be implemented relatively close to a diversity antenna 420 so as to minimize or reduce losses and/or noise in a signal path 422.

The diversity RX module 150 in the example of FIG. 12 can be configured such that switches 410 and 412, as well as LNAs 414, are implemented in a semiconductor die (depicted as 116) that is mounted underneath a packaging substrate, such as the packaging substrate 102 described with reference to various embodiments above. One or more filters 400 can be mounted on such a packaging substrate as described herein.

As further shown in FIG. 12, RX signals processed by the diversity RX module 150 can be routed to a transceiver through a signal path 424. In wireless applications where the signal path 424 is relatively long and lossy, the foregoing implementation of the diversity RX module 150 close to the antenna 420 can provide a number of desirable features.

It will be understood that one or more features of the present disclosure can also be implemented in dual-sided packaged RF modules having functionalities different than that of the diversity receive example of FIG. 12. For example, for any packaged BGA-based module with an underside molding on the underside, having one or more features as described herein can be implemented.

FIG. 13 shows that in some embodiment a dual-sided packaged RF module having one or more features as described herein can be implemented in a wireless device 500. For example, an LNA or LNA-related module 150 can be implemented as a dual-sided packaged RF module as described herein, and such a module can be utilized with a main antenna 524.

The example LNA module 150 of FIG. 13 can include, for example, one or more LNAs 116, a bias/logic circuit 432, and a band-selection switch 430. Some or all of such circuits can be implemented in a semiconductor die that is mounted under a packaging substrate of the LNA module 150. In such a LNA module 150, some or all of duplexers 400 can be mounted on the packaging substrate so as to form a dual-sided packaged RF module having one or more features as described herein.

FIG. 13 further depicts various features associated with the example wireless device 500. Although not specifically shown in FIG. 13, a diversity RX module 100 of FIG. 12 can be included in the wireless device 500 with the LNA module 150, in place of the LNA module 150, or any combination thereof. It will also be understood that a dual-sided packaged RF module having one or more features as described herein can be implemented in the wireless device 500 as a non-LNA module.

In the example wireless device 500, a power amplifier (PA) circuit 518 having a plurality of PAs can provide an amplified RF signal to a switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

The transceiver 514 is shown to interact with a baseband sub-system 510 that is configured to provide conversion between data and/or voice signals suitable for a user and RF signals suitable for the transceiver 514. The transceiver 514 is also shown to be connected to a power management component 506 that is configured to manage power for the operation of the wireless device 500. Such a power management component can also control operations of the baseband sub-system 510.

The baseband sub-system 510 is shown to be connected to a user interface 502 to facilitate various input and output of voice and/or data provided to and received from the user. The baseband sub-system 510 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 25 GHz.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including”, and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly coupled, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel filters, multiplexer, devices, modules, wireless communication devices, apparatus, methods, and systems described herein may be embodied in a variety of other forms. Furthermore, various omissions, substitutions and changes in the form of the filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A dual-sided packaged radio-frequency (RF) module comprising:
a packaging substrate having a first surface with at least one RF circuit component mounted thereon and a second surface opposite to the first surface with at least one circuitry component mounted thereon;
at least one contact feature attached to the second surface of the packaging substrate, a vertical extension of the at least one contact feature being larger than a distance between a bottom surface of the at least one circuitry component and the second surface of the packaging substrate;
an underside molding encapsulating the at least one circuitry component and the at least one contact feature, a bottom surface of the underside molding being flush with the bottom surface of the at least one circuitry component; and
a trench structure formed in the underside molding around the at least one contact feature.

2. The dual-sided packaged RF module of claim 1 wherein the at least one contact feature includes a solder ball having a diameter that is larger than a thickness of the underside molding.

3. The dual-sided packaged RF module of claim 2 wherein the diameter of the solder ball is larger than twice the thickness of the underside molding.

4. The dual-sided packaged RF module of claim 2 wherein the trench structure is formed circumferentially around the solder ball.

5. The dual-sided packaged RF module of claim 1 wherein the trench structure comprises a recess of triangular or trapezoidal cross-section running around an edge of a portion of the solder ball exposed from the underside molding, and a width of the recess of the trench structure gradually decreases when followed from the bottom surface of the underside molding towards the second surface of the packaging substrate.

6. The dual-sided packaged RF module of claim 1 comprising a number of contact features forming a ball grid array (BGA) or land grid array (LGA) on the bottom surface of the underside molding.

7. The dual-sided packaged RF module of claim 1 further comprising an overmold encapsulating the at least one RF circuit component mounted on the first surface of the packaging substrate.

8. The dual-sided packaged RF module of claim 2 wherein the solder ball comprises a solder ball core enclosed by surrounding solder material including a solder alloy, the solder ball core being formed from a material different from the surrounding solder material.

9. The dual-sided packaged RF module of claim 8 wherein the solder ball core has the shape of a partially cut-away sphere, a cutting plane of the partially cut-away sphere being flush with the bottom surface of the underside molding.

10. The dual-sided packaged RF module of claim 1 wherein the dual-sided packaged RF module is implemented as a power amplifier (PA) module, a low-noise amplifier (LNA) module, a front-end module (FEM), or a switching module.

11. A dual-sided packaged radio-frequency (RF) module comprising:
a packaging substrate having a first surface with at least one RF circuit component mounted thereon and a second surface opposite to the first surface with at least one circuitry component mounted thereon;
at least one solder ball attached to the second surface of the packaging substrate, a vertical extension of the at least one solder ball being larger than a distance between a bottom surface of the at least one circuitry component and the second surface of the packaging substrate, the at least one solder ball including a solder ball core enclosed by surrounding solder material, the solder ball core being formed from a material different from the surrounding solder material; and
an underside molding encapsulating the at least one circuitry component and the at least one solder ball, a bottom surface of the underside molding being flush with the bottom surface of the at least one circuitry component.

12. The dual-sided packaged RF module of claim 11 wherein the vertical extension of the at least one solder ball is larger than twice the distance between the bottom surface of the at least one circuitry component and the second surface of the packaging substrate.

13. The dual-sided packaged RF module of claim 11 comprising a number of solder balls forming a ball grid array (BGA) on the bottom surface of the underside molding.

14. The dual-sided packaged RF module of claim 11 wherein the surrounding solder material includes a solder alloy.

15. The dual-sided packaged RF module of claim 11 wherein the solder ball core has a shape of a partially cut-away sphere, a cutting plane of the partially cut-away sphere being flush with the bottom surface of the underside molding.

16. The dual-sided packaged RF module of claim 11 wherein the dual-sided packaged RF module is implemented as a power amplifier (PA) module, a low-noise amplifier (LNA) module, a front-end module (FEM), or a switching module.

17. A wireless device comprising:
a dual-sided packaged radio-frequency (RF) module, the dual-sided packaged RF module comprising a packaging substrate having a first surface with at least one RF circuit component mounted thereon and a second surface opposite to the first surface with at least one circuitry component mounted thereon, at least one contact feature attached to the second surface of the packaging substrate, a vertical extension of the at least one contact feature being larger than a distance between a bottom surface of the at least one circuitry component and the second surface of the packaging substrate, an underside molding encapsulating the at least one circuitry component and the at least one contact feature, a bottom surface of the underside molding being flush with the bottom surface of the at least one circuitry component, and a trench structure formed in the underside molding around the at least one contact feature; and
an antenna coupled to the dual-sided packaged RF module.

18. The wireless device of claim 17 wherein the dual-sided packaged RF module is implemented as a diversity receive (RX) module.

19. The wireless device of claim 18 wherein the at least one RF circuit component includes one or more surface-mount technology (SMT) devices.

20. The wireless device of claim 18 wherein the at least one circuitry component mounted on the second surface of the packaging substrate includes at least one of power amplifiers (PA), low noise amplifiers (LNA), and switches.
